(19) United States
(12) Patent Application Publication
(10) Pub. No.: US 2025/0198857 A1
(43) Pub. Date: Jun. 19, 2025

(54) Method for Calibrating Temperature-Measuring Substrate, System for Measuring Substrate Temperature, and Temperature-Measuring Substrate

(71) Applicant: Tokyo Electron Limited, Tokyo (JP)

(72) Inventor: Tomohiro OTA, Yamanashi (JP)

(21) Appl. No.: 19/072,662

(22) Filed: Mar. 6, 2025

Related U.S. Application Data
(63) Continuation of application No. PCT/JP2023/031710, filed on Aug. 31, 2023.

(30) Foreign Application Priority Data
Sep. 20, 2022 (JP) 2022-149201

(51) Int. Cl. G01K 15/00; G01K 7/16

(52) U.S. Cl. CPC G01K 15/005; G01K 7/16

(57) ABSTRACT

A method for calibrating a temperature-measuring substrate having a plurality of temperature-measuring resistors and electrodes arranged to correspond to the plurality of temperature-measuring resistors is disclosed. The method comprises: bringing a needle-shaped body into contact with an electrode corresponding to at least one temperature-measuring resistor; immersing the temperature-measuring substrate into an insulating coolant; measuring an electrical resistance value of the temperature-measuring resistor through the electrode using the needle-shaped body; measuring a temperature of the insulating coolant; and acquiring a correction value for converting the measured electrical resistance value to the measured temperature of the insulating coolant.

### CROSS-REFERENCE TO RELATED APPLICATIONS

This application is a bypass continuation application of International Application No. PCT/JP2023/031710 having an international filing date of Aug. 31, 2023 and designating the United States, the International Application being based upon and claiming the benefit of priority from Japanese Patent Application No. 2022-149201 filed on Sep. 20, 2022, the entire contents of which are incorporated herein by reference.

### TECHNICAL FIELD

The present disclosure relates to a method for calibrating a temperature-measuring substrate, a substrate temperature-measuring system, and a temperature-measuring substrate.

### BACKGROUND

A prober is known as a substrate inspection device for inspecting a plurality of semiconductor devices formed on a product wafer. The prober includes a probe card having contact probes, i.e., a plurality of needle-shaped contact terminals. By making the product wafer placed on a placing table close to the probe card, the contact probes are brought into contact with electrode pads or solder bumps of the semiconductor devices. The prober inspects electrical connection states of electric circuits of the semiconductor devices by causing electricity to flow from the contact probes to the electric circuits of the semiconductor devices.

Recently, the inspection conditions for inspecting semiconductor devices have become complicated, and it is particularly required to inspect semiconductor devices in a high-temperature and low-temperature environment. In the prober, the high-temperature and low-temperature environment is realized by temperature adjustment using a Peltier element or a heater of the placing table on which the product wafer is placed. Further, instead of the product wafer, a temperature-measuring wafer (see, e.g., KLA Corporation, “Process Probe™ 1530/1535,” [online], [searched on Aug. 12, 2022], Internet <URL: https://www.kla.com/products/chip-manufacturing/in-situ-process-management>, hereinafter, Non-Patent Document 1) is placed on the placing table and the temperature of the placing table is measured to check whether or not the desired high-temperature or low-temperature environment can be realized. In other words, the temperature adjustment performance of the placing table is checked.

### SUMMARY

The technique of the present disclosure improves the efficiency of temperature measurement using a temperature-measuring substrate.

According to one aspect of the present disclosure, a method for calibrating a temperature-measuring substrate having a plurality of temperature-measuring resistors and electrodes arranged to correspond to the plurality of temperature-measuring resistors is disclosed. The method comprises: bringing a needle-shaped body into contact with an electrode corresponding to at least one temperature-measuring resistor; immersing the temperature-measuring substrate into an insulating coolant; measuring an electrical resistance value of the temperature-measuring resistor through the electrode using the needle-shaped body; measuring a temperature of the insulating coolant; and acquiring a correction value for converting the measured electrical resistance value to the measured temperature of the insulating coolant.

### BRIEF DESCRIPTION OF THE DRAWINGS

FIG. 1 is a plan view showing a configuration of a temperature-measuring wafer according to an embodiment of the technique of the present disclosure.

FIG. 2 is a front view showing a configuration of an example of a substrate inspection device for inspecting semiconductor devices formed on a product wafer.

FIG. 3 is a front view showing a configuration of a modification of a substrate inspection device for inspecting semiconductor devices formed on a product wafer.

FIG. 4 is a front view showing a configuration of an example of a substrate inspection device for acquiring a correction value for each pattern on a temperature-measuring wafer.

FIG. 5A is a process diagram for explaining an example of a correction value calibration operation using the substrate inspection device of FIG. 4.

FIG. 5B is a process diagram for explaining an example of the correction value calibration operation using the substrate inspection device of FIG. 4.

FIG. 5C is a process diagram for explaining an example of the correction value calibration operation using the substrate inspection device of FIG. 4.

FIG. 5D is a process diagram for explaining an example of the correction value calibration operation using the substrate inspection device of FIG. 4.

FIG. 6A is a process diagram for explaining a modification of a correction value calibration operation using the substrate inspection device of FIG. 4.

FIG. 6B is a process diagram for explaining a modification of the correction value calibration operation using the substrate inspection device of FIG. 4.

FIG. 6C is a process diagram for explaining a modification of the correction value calibration operation using the substrate inspection device of FIG. 4.

FIG. 7A is a front view schematically showing a configuration of a modification of a substrate inspection device for acquiring a correction value for each pattern on a temperature-measuring wafer.

FIG. 7B is a front view schematically showing a configuration of a modification of a substrate inspection device for acquiring a correction value for each pattern on a temperature-measuring wafer.

FIG. 8 is a diagram for explaining a correction value calibration operation using the substrate inspection device of FIG. 2.

FIG. 9 is a plan view schematically showing a configuration of a modification of a temperature-measuring wafer according to an embodiment of the technique of the present disclosure.

FIG. 10 is a diagram for explaining a modification of arrangement of heaters in the temperature-measuring wafer of FIG. 9.

### DETAILED DESCRIPTION

In the temperature-measuring wafer according to the technique of Non-Patent Document 1, a plurality of temperature-measuring sensors are distributed on the temperature-measuring wafer, and wiring is connected from each temperature-measuring sensor to extract the output of each temperature-measuring sensor. Therefore, a plurality of wiring is present on the temperature-measuring wafer, which is not easy to handle, and the temperature-measuring wafer needs to be handled manually by an operator.

Further, if the heat capacity of each wiring increases, the thermal energy from the placing table escapes to each wiring, making it impossible to reproduce the actual inspection environment. Therefore, each wiring is made very thin to prevent a large amount of thermal energy from escaping. However, thinner wiring is more prone to breakage, necessitating more frequent calibration operations for the temperature-measuring wafer, which also serves to check whether or not any wiring has broken. The calibration operation of the temperature-measuring wafer is performed using a calibration device capable of controlling the temperature of the temperature-measuring wafer.

However, as described above, the temperature-measuring wafer needs to be handled manually by an operator, and the calibration of the temperature-measuring wafer is labor-intensive. In other words, in the case of using the temperature-measuring wafer according to the technique of Non-Patent Document 1, the calibration operation, which is labor-intensive, needs to be performed frequently, and it is not possible to check the temperature adjustment performance of the placing table using the temperature-measuring wafer whenever the calibration operation is performed. Therefore, the efficiency of temperature measurement using the temperature-measuring wafer deteriorates.

On the other hand, in the technique of the present disclosure, in the case of performing the calibration operation of the temperature-measuring substrate, needle-shaped bodies are brought into contact with electrodes of the temperature-measuring substrate, the electrodes being arranged to correspond to a plurality of temperature-measuring resistors of the temperature-measuring substrate. Further, the temperature-measuring substrate is immersed into an insulating coolant, and electricity is caused to flow from the needle-shaped bodies to the temperature-measuring resistors via the electrodes, thereby measuring the electrical resistance values of the temperature-measuring resistors and also measuring the temperature of the insulating coolant. Next, a correction value for converting the measured electrical resistance values into the measured temperature of the insulating coolant is acquired.

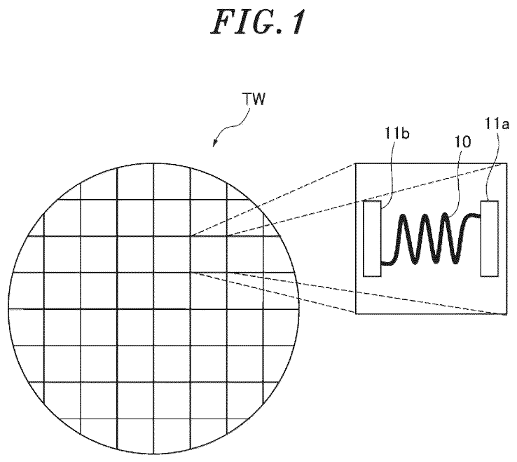

Hereinafter, an embodiment of the technique of the present disclosure will be described with reference to the accompanying drawings. FIG. 1 is a plan view showing a schematic configuration of a temperature-measuring wafer TW (temperature-measuring substrate) according to an embodiment of the technique of the present disclosure.

In FIG. 1, the temperature-measuring wafer TW is a disc-shaped substrate having substantially the same shape as that of a product wafer (product substrate), which is a semiconductor wafer, and a plurality of patterns 10 formed of temperature-measuring resistors are formed at positions corresponding to semiconductor devices formed on the product wafer. The temperature-measuring resistors of the patterns 10 are made of a metal or metal oxide whose electrical resistance value changes depending on temperatures. In the present embodiment, platinum is used, for example. Each pattern 10 may be provided on the surface of the temperature-measuring wafer TW, or may be embedded in the temperature-measuring wafer TW.

Further, electrode pads 11a and 11b are arranged at both ends of each pattern 10 on the temperature-measuring wafer TW. The electrode pads 11a and 11b are provided on the surface of the temperature-measuring wafer TW, and are brought into contact with contact probes 22 of a probe card 20 which will be described later.

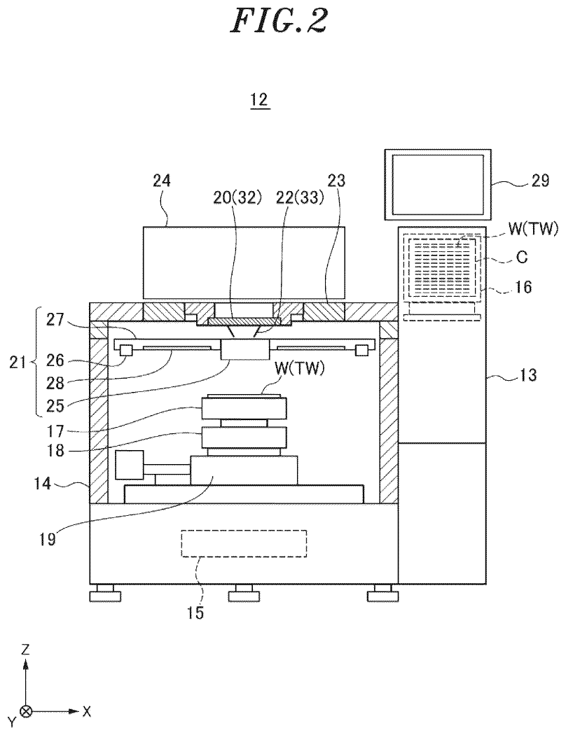

FIG. 2 is a front view showing a schematic configuration of a substrate inspection device 12 for inspecting semiconductor devices formed on the product wafer W. In FIG. 2, a part of the substrate inspection device 12 is shown as a cross sectional view to show the internal structure.

In FIG. 2, the substrate inspection device 12 has a loader part 13, an inspection part 14, and a device controller 15. Under the control of the device controller 15, the substrate inspection device 12 transfers the product wafer W from the loader part 13 to the inspection part 14, and inspects devices under test (DUTs), which are a plurality of semiconductor devices formed on the product wafer W. Specifically, the substrate inspection device 12 inspects the electrical connection states of the electrical circuits of the DUTs by causing electricity to flow through the electrical circuits.

The loader part 13 has a cassette storage part 16 and a wafer transfer mechanism (not shown). The cassette storage part 16 stores a cassette C accommodating product wafers W. The cassette C is, e.g., a front opening unified pod (FOUP). The wafer transfer mechanism transfers the product wafer W between the cassettes C stored in the cassette storage part 16 and a stage 17 (to be described later) provided in the inspection part 14.

The inspection part 14 is disposed adjacent to the loader part 13. The inspection part 14 has a stage 17, a lifting mechanism 18, an XY driving mechanism 19, a probe card 20, and an alignment mechanism 21.

The stage 17 (placing member) has a substrate attraction mechanism, such as a vacuum chuck or an electrostatic chuck, and further has a temperature adjustment mechanism (not shown), such as a Peltier element or a heater. Further, the product wafer W is placed on the upper surface of the stage 17, and is attracted by the substrate attraction mechanism. The temperature of the stage 17 is adjusted by the temperature adjustment mechanism, so that the temperature of the product wafer W is adjusted by heat transfer.

The lifting mechanism 18 is disposed below the stage 17 and moves the stage 17 vertically (in the Z direction in the drawing). The XY driving mechanism 19, which is disposed below the lifting mechanism 18 and fixed to the bottom portion of the inspection part 14, moves the stage 17 and the lifting mechanism 18 in two axial directions (the X direction and the Y direction in the drawing).

The probe card 20 is disposed above the stage 17. A plurality of contact probes 22 that are needle-shaped bodies are formed on the stage 17 side of the probe card 20. Further, the probe card 20 is detachably attached to the head plate 23. A tester (not shown) is connected to the probe card 20 via a test head 24.

The alignment mechanism 21 has a camera 25, a guide rail 26, a main bridge 27, and a light source 28. The camera 25, which is, e.g., a CCD camera or a CMOS camera, is mounted downward at the center of the main bridge 27 to capture images of the stage 17 and the product wafer W.

The guide rail 26 supports the main bridge 27 so that it can move in the horizontal direction (the Y direction in the drawing). The main bridge 27 is supported by a pair of left and right guide rails 26, and moves in the horizontal direction (the Y direction in the drawing) along the guide rails 26. The camera 25 moves between a standby position and a position directly below the center of the probe card 20 (hereinafter, referred to as “probe center”) by the movement of the main bridge 27.

In the case of performing alignment to be described below, the camera 25 is located at the probe center, and captures, from the top, images of the electrode pads of the DUTs of the product wafer W placed on the stage 17 moving in the XY directions. By using the captured image, the positions of the electrode pads of the DUTs are acquired. Further, the captured images are displayed on a display device 29. The light source 28 is disposed under the main bridge 27, irradiates light to the stage 17, and assists the camera 25 in capturing the images of the electrode pads.

In the substrate inspection device 12, in the case of inspecting the DUTs of the product wafer W, first, the inspection part 14 attracts the product wafer W placed on the stage 17 to the stage 17, and adjusts the temperature of the stage 17 on which the product wafer W is placed to a desired temperature. Next, based on the acquired positions of the electrode pads of the DUTs, the alignment mechanism 21 cooperates with the XY driving mechanism 19 to perform alignment such that the contact probes 22 of the probe card 20 face the electrode pads of the DUTs of the product wafer W.

Then, the lift mechanism 18 raises the stage 17 to bring the contact probes 22 of the probe card 20 into contact with the electrode pads of the corresponding DUTs. Thereafter, the device controller 15 inspects the electrical connection states of the electric circuits of the DUTs by causing electricity to flow from the tester to the electric circuits of the DUTs through the test head 24 and the contact probes 22 of the probe card 20.

The device controller 15 is disposed under the stage 17, and controls the overall operation of the substrate inspection device 12. The CPU provided in the device controller 15 performs desired inspection depending on product parameters stored in the memory, such as a read only memory (ROM), a random access memory (RAM), or the like. The product parameters may be stored in a semiconductor memory other than a hard disk, a ROM, or a RAM. Further, the product parameters may be recorded on a computer-readable recording medium, such as a CD-ROM, a DVD, or the like, inserted at a predetermined position, and read out.

Further, in the substrate inspection device 12, in addition to the above-described inspection of the DUTs of the product wafer W, the temperature adjustment performance of the temperature adjustment mechanism of the stage 17 (hereinafter, collectively referred to as “stage calibration operation”) is checked and adjusted. In the stage calibration operation, a temperature-measuring wafer TW is used to check whether or not the temperature of each pattern 10 of the temperature-measuring wafer TW can be adjusted to a desired temperature, e.g., an inspection temperature, by the temperature adjustment mechanism of the stage 17. In other words, the temperature of each pattern 10 of the temperature-measuring wafer TW is measured.

In the case of performing the stage calibration operation, a temperature-measuring probe card 32 (to be described later), instead of the probe card 20, is attached to the head plate 23, and the temperature-measuring wafer TW of FIG. 1 is used, in place of the product wafer W. The temperature-measuring probe card 32 has a structure that is basically the same as that of the probe card 20, and has a plurality of temperature-measuring contact probes 33 to be in contact with the electrode pads 11a and 11b of each pattern 10 of the temperature-measuring wafer TW.

In the substrate inspection device 12, in the case of performing the stage calibration operation, first, the inspection part 14 attracts the temperature-measuring wafer TW placed on the stage 17 to the stage 17, and adjusts the temperature of the stage 17 on which the temperature-measuring wafer TW is placed to the inspection temperature. Then, the positions of the electrode pads 11a and 11b of each pattern 10 are acquired by capturing images using the camera 25. Thereafter, based on the acquired positions of the electrode pads 11a and 11b, the alignment mechanism 21 cooperates with the XY driving mechanism 19 to perform alignment such that the temperature-measuring contact probes 33 of the temperature-measuring probe card 32 face the electrode pads 11a and 11b of each pattern 10.

Then, the lifting mechanism 18 raises the stage 17, and the temperature-measuring contact probes 33 of the temperature-measuring probe card 32 are brought into contact with the corresponding electrode pads 11a and 11b of each pattern 10. Next, the device controller 15 measures the electrical resistance value of each pattern 10 by causing electricity to flow from the tester to each pattern 10 through the test head 24 and the temperature-measuring contact probes 33 of the temperature-measuring probe card 32. The measured electrical resistance is converted to a temperature by the tester or the device controller 15 based on the correction value for each pattern 10 which will be described later. Accordingly, it is checked whether or not the temperature adjustment mechanism of the stage 17 can adjust the temperature of each pattern 10 of the temperature-measuring wafer TW to the inspection temperature. If the temperature of each pattern 10 cannot be adjusted to the inspection temperature, the difference between the converted temperature and the temperature measured by the temperature sensor in the stage 17 (inspection temperature) is recorded as a correction value, and the temperature of the stage 17 is adjusted by reflecting the recorded correction value to subsequent temperature measurement using the temperature-measuring wafer TW.

When the probe card 20 is replaced with the temperature-measuring probe card 32, the tester connected to the test head 24 also need to be replaced with a tester for the temperature-measuring probe card. However, it is considered to install a wireless communication part, e.g., Bluetooth (registered trademark), for performing short-range wireless communication with a battery at the temperature-measuring probe card 32. In this case, the measurement result of the electrical resistance value of each pattern 10 is transmitted to a separate tester, which is different from the tester connected to the test head 24, and the temperature is converted by this separate tester. Accordingly, it is unnecessary to replace the tester connected to the test head 24 in the case of performing the stage calibration operation, and the efficiency of the stage calibration operation in the substrate inspection device 12 can be improved.

In the above-described stage calibration operation, the probe card 20 needs to be replaced with the temperature-measuring probe card 32. However, if the replacement operation is performed manually by an operator, the efficiency of the stage calibration operation may deteriorate. Therefore, in the modification of the substrate inspection device 12, the temperature-measuring probe card 32 is attached to other component, instead of the head plate 23, and the stage calibration operation is performed without replacing the probe card 20 with the temperature-measuring probe card 32.

FIG. 3 is a front view showing the configuration of a substrate inspection device 30 as the modification of the substrate inspection device 12 in FIG. 2. In FIG. 3, a part of the substrate inspection device 30 is shown in cross section to show the internal structure. Since the configuration of the substrate inspection device 30 is basically the same as that of the substrate inspection device 12, only the configuration and operation that are different from those of the substrate inspection device 12 will be described below.

In FIG. 3, in the substrate inspection device 30, a card base 31, instead of the camera 25, is attached to the center of the main bridge 27, and a temperature-measuring probe card 32 is attached to the bottom surface of the card base 31 to face the stage 17.

In the case of performing the stage calibration operation using the temperature-measuring probe card 32 attached to the card base 31, first, the temperature of the stage 17 that attracts the temperature-measuring wafer TW is adjusted to the inspection temperature. Then, a camera (not shown) disposed at the card base 31 captures images of the electrode pads 11a and 11b of each pattern 10 of the temperature-measuring wafer TW from the top. By using the captured images, the positions of the electrode pads 11a and 11b of each pattern 10 are acquired.

Next, based on the acquired positions of the electrode pads 11a and 11b of each pattern 10, the alignment mechanism 21 cooperates with the XY driving mechanism 19 to make the temperature-measuring contact probes 33 face the electrode pads 11a and 11b of each pattern 10 of the temperature-measuring wafer TW. Then, the lifting mechanism 18 raises the stage 17 to bring the temperature-measuring contact probes 33 of the temperature-measuring probe card 32 into contact with the electrode pads 11a and 11b of the corresponding patterns 10, thereby measuring the electrical resistance value of each pattern 10.

Further, the substrate inspection device 30 of FIG. 3 may include a transfer robot 34 for the temperature-measuring probe card 32. The transfer robot 34 has a movable main body 35, an articulated arm 36, and a card base 37 attached to the tip of the arm 36. The temperature-measuring probe card 32 is attached to the bottom surface of the card base 37.

When the transfer robot 34 performs the stage calibration operation, first, the temperature of the stage 17 that attracts the temperature-measuring wafer TW is adjusted to the inspection temperature. Then, the transfer robot 34 captures images of the electrode pads 11a and 11b of each pattern 10 of the temperature-measuring wafer TW from the top using a camera (not shown) disposed at the card base 37. The transfer robot 34 acquires the positions of the electrode pads 11a and 11b of each pattern 10 from the captured images.

Then, the transfer robot 34 moves the arm 36 based on the acquired positions of the electrode pads 11a and 11b of each pattern 10, and makes the temperature-measuring contact probes 33 face the electrode pads 11a and 11b of each pattern 10 of the temperature-measuring wafer TW. Further, the arm 36 moves the card base 37 downward, and the lifting mechanism 18 raises the stage 17, so that the temperature-measuring contact probes 33 of the temperature-measuring probe card 32 are brought into contact with the electrode pads 11a and 11b of the corresponding pattern 10. Then, the electrical resistance value of each pattern 10 is measured.

Further, when the transfer robot 34 performs the stage calibration operation, the head plate 23 is lifted upward to expose the stage 17 of the inspection part 14. Accordingly, the temperature-measuring probe card 32 attached to the card base 37 of the transfer robot 34 can reach the temperature-measuring wafer TW attracted to the stage 17 without interfering with the probe card 20 attached to the head plate 23.

In the substrate inspection device 30 of FIG. 3, in the case of performing the stage calibration operation, it is not necessary to replace the probe card 20 attached to the head plate 23 with the temperature-measuring probe card 32. Hence, the efficiency of the stage calibration operation can be improved.

Since each pattern 10 of the temperature-measuring wafer TW is made of platinum as described above, it is considered that the temperature of each pattern 10 can be acquired by converting the measured electrical resistance value of each pattern 10 of the temperature-measuring wafer TW into a temperature based on the temperature resistance characteristics of platinum. However, the measured electrical resistance value is affected not only by the electrical resistance value of the pattern 10 but also by the electrical resistance value of the electrode pads 11a and 11b. Therefore, the actual temperature of each pattern 10 cannot be accurately acquired simply by converting the measured electrical resistance value to a temperature based on the temperature resistance characteristics of platinum. Hence, in the temperature-measuring wafer TW, the correction value for converting the measured electrical resistance value to an actual temperature is acquired for each pattern 10. Since the temperature-measuring wafer TW is used repeatedly, aging, such as changes in the connection state between each pattern 10 and the electrode pad 11a and 11b, occurs. Accordingly, if the previously acquired correction value continues to be used, it may be difficult to accurately convert the measured electrical resistance value to the actual temperature. Thus, in the temperature-measuring wafer TW, the correction value is periodically reacquired. In the present embodiment, the reacquisition of the correction value for each pattern 10 of the temperature-measuring wafer TW is referred to as “correction value calibration operation.”

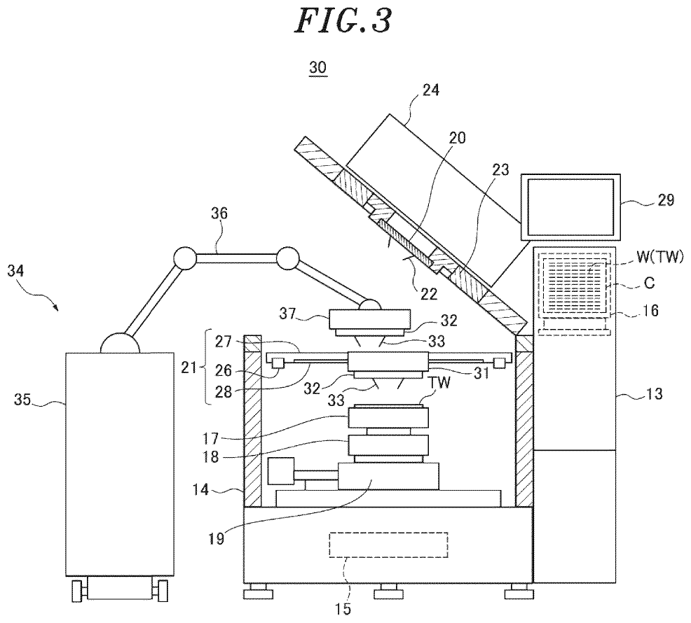

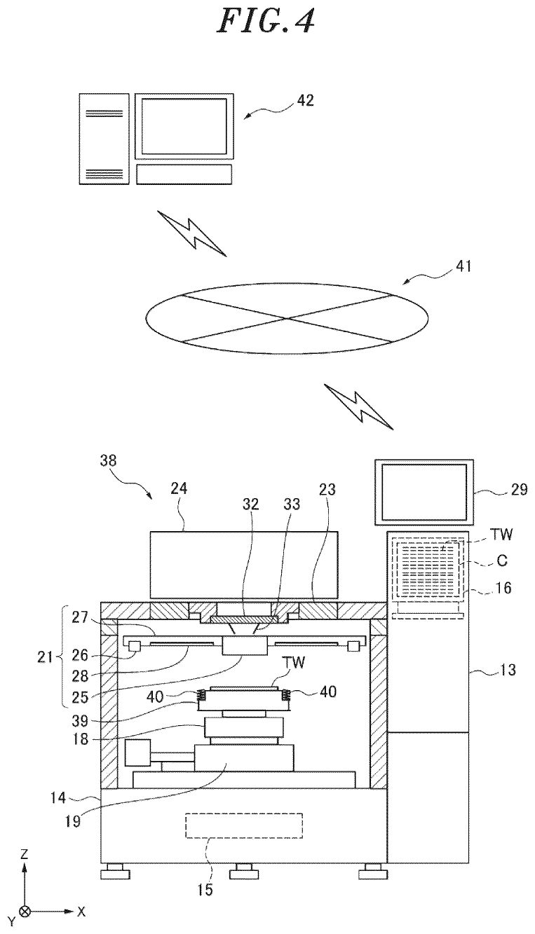

FIG. 4 is a front view showing a schematic configuration of a substrate inspection device 38 (calibration device) that acquires the correction value for each pattern 10 of the temperature-measuring wafer TW. In FIG. 4, a part of the substrate inspection device 38 is also shown as a cross sectional view to show the internal structure of the substrate inspection device 38. Since the configuration of the substrate inspection device 38 is basically the same as that of the substrate inspection device 12, only the configuration and operation that are different from those of the substrate inspection device 12 will be described below.

In FIG. 4, in the substrate inspection device 38, the temperature-measuring wafer TW is stored in the cassette C, and the temperature-measuring probe card 32, instead of the probe card 20, is attached to the head plate 23. Further, the inspection part 14 has a calibration stage 39 instead of the stage 17. The calibration stage 39 is a substantially disc-shaped placing base, and has a temperature adjustment mechanism (not shown), such as a Peltier element or a heater, similarly to the stage 17. Further, the calibration stage 39 has a bellows 40 that is disposed along the periphery thereof and is extensible/contractible in the vertical direction (the Z direction in the drawing). The substrate inspection device 38 is configured to be able to communicate with an external information processing device, e.g., a server 42, via an information communication network, e.g., the Internet 41.

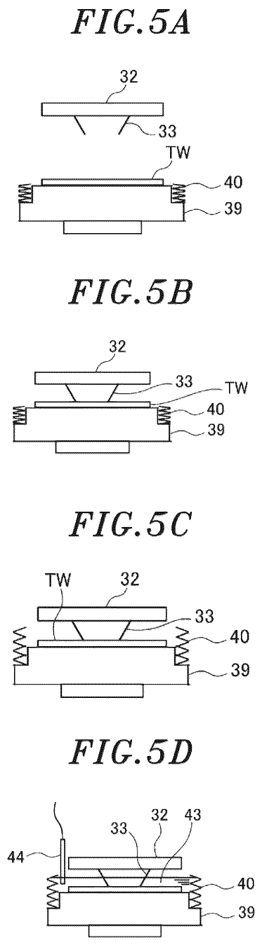

FIGS. 5A-5D are process diagrams for explaining the correction value calibration operation using the substrate inspection device 38 of FIG. 4. First, in the substrate inspection device 38, the camera 25 captures images of the electrode pads 11a and 11b of each pattern 10 of the temperature-measuring wafer TW placed on the calibration stage 39 located at the probe center from the top. The captured image are used for acquiring the positions of the electrode pads 11a and 11b of each pattern 10.

Then, based on the acquired positions of the electrode pads 11a and 11b of each pattern 10, the alignment mechanism 21 cooperates with the XY driving mechanism 19 to make the temperature-measuring contact probes 33 face the electrode pads 11a and 11b of each pattern 10 (see FIG. 5A). Next, the lifting mechanism 18 lifts the stage 17 to bring the temperature-measuring contact probes 33 of the temperature-measuring probe card 32 into contact with the corresponding electrode pads 11a and 11b of each pattern 10 (see FIG. 5B).

Then, the bellows 40 is extended upward in the drawing. In this case, the bellows 40 is extended such that the upper end of the bellows 40 becomes sufficiently higher than the temperature-measuring wafer TW (see FIG. 5C). Thereafter, an insulating coolant 43, e.g., hydrofluoroether (HFT), is supplied from a coolant supply port (not shown) disposed at the calibration stage 39 to the space surrounded by the bellows 40 (hereinafter, referred to as “coolant space”), and the temperature-measuring wafer TW placed on the calibration stage 39 is immersed into the insulating coolant 43 (see FIG. 5D).

Here, the insulating coolant 43 supplied to the coolant space circulates between the coolant space and an external chiller (temperature adjustment device), and the temperature is adjusted to a desired temperature by the chiller. Further, the chiller can perform cooling of the circulating insulating coolant 43 as well as heating of the circulating insulating coolant 43. By adjusting the temperature of the calibration stage 39 using the temperature adjustment mechanism, the temperature of the insulating coolant 43 in the coolant space is maintained at a desired temperature. The difference between the temperature of the temperature-measuring wafer TW and the temperature (desired temperature) of the insulating coolant 43 is substantially eliminated as time elapses due to the heat exchange between the temperature-measuring wafer TW and the insulating coolant 43. Accordingly, the temperature of the temperature-measuring wafer TW is adjusted to the desired temperature.

In the present embodiment, since no wiring is attached to the temperature-measuring wafer TW, no wiring floats in the coolant space. Thus, a stirring device or a convection device (both not shown) can be easily arranged in the coolant space. Accordingly, the insulating coolant 43 can be stirred or circulated in the coolant space, thereby improving the uniformity of the temperature of the insulating coolant 43.

The temperature of the insulating coolant 43 is measured by a high-precision temperature sensor 44 of the substrate inspection device 38. After the temperature of the insulating coolant 43 has stabilized, electricity is caused to flow through each pattern 10 through the temperature-measuring contact probes 33 of the temperature-measuring probe card 32, thereby measuring the electrical resistance value of each pattern 10. In this case, the electrical resistance values of the plurality of patterns 10 may be measured, or the electrical resistance value of only one pattern 10 may be measured.

Then, the tester or the device controller 15 acquires a correction value for converting the measured electrical resistance value for each pattern 10 into the temperature of the insulating coolant 43 measured by the high-precision temperature sensor 44. Next, the acquired correction value is stored in the memory (storage device) of the server 42 in association with the pattern 10 whose electrical resistance value used for acquiring the correction value is measured. For example, the acquired correction value is stored in association with the identification number of the corresponding pattern 10. Then, the correction value calibration operation is completed.

As described above, in the present embodiment, the reacquired correction value of each pattern 10 is stored in the memory of the server 42, which is different from that of the substrate inspection device 38, and the server 42 is connected to the Internet 41. Therefore, by connecting the substrate inspection device 12 or the substrate inspection device 30 to the Internet 41, it is possible to use the reacquired correction value for each pattern 10 stored in the memory of the server 42. For example, when the substrate inspection device 12 or the substrate inspection device 30 performs the stage calibration operation, the identification number of each pattern 10 of the temperature-measuring wafer TW, which is read by capturing images using the camera, is transmitted to the server 42 via the Internet 41. The server 42 transmits the received correction value associated with the identification number of each pattern 10 to the substrate inspection device 12 or the substrate inspection device 30. The device controller 15 or the tester of the substrate inspection device 12 or the substrate inspection device 30, which has received the transmitted correction value for each pattern 10, converts the measured electrical resistance value of each pattern 10 into a temperature using the received correction value. Accordingly, the substrate inspection device 12 or the substrate inspection device 30 can accurately check the temperature adjustment performance of the temperature adjustment mechanism of the stage 17 using the correction value for each pattern 10 that is reacquired by the correction value calibration operation regardless of the installation location.

Further, as described above, the substrate inspection device 38 has basically the same configuration as that of the substrate inspection device 12, and thus can be easily installed in an inspection line for the product wafer W in the plurality of substrate inspection devices 12. Accordingly, not only the stage calibration operation of each substrate inspection device 12 but also the correction value calibration operation of the temperature-measuring wafer TW can be performed in the corresponding inspection line, thereby improving the operation efficiency.

Further, for example, it is considered that the manufacturer of the substrate inspection device 12 acquires the correction value for each pattern 10 of the temperature-measuring wafer TW using the substrate inspection device 38 before shipping the substrate inspection device 12 to the customer, and stores the acquired correction value in the memory of the server 42. In this case, the customer can use the correction value stored in the memory of the server 42, so that it is unnecessary to acquire the correction value for each pattern 10 after the substrate inspection device 12 is installed at the customer's site. Accordingly, the substrate inspection device 12 can be put into operation quickly at the customer's site.

In the present embodiment, the substrate inspection device 12 or the substrate inspection device 30, the substrate inspection device 38, and the server 42 are connected to each other via the Internet 41 so that they can communicate with each other. Therefore, it can be said that they constitute a substrate temperature-measuring system for measuring a temperature using the temperature-measuring wafer TW (evaluating the temperature adjustment performance of the temperature adjustment mechanism of the stage 17).

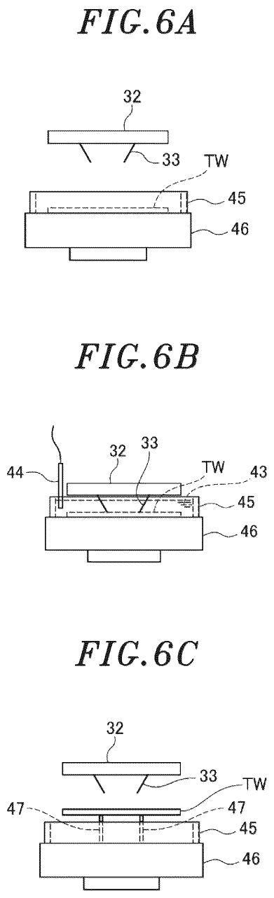

In the substrate inspection device 38, the calibration stage 39 provided with the bellows 40 was used. However, instead of the calibration stage 39, a calibration stage 46 provided with a sidewall 45 may be used (see FIG. 6A). The calibration stage 46 is also a substantially disc-shaped placing table, and has a temperature adjustment mechanism (not shown), such as a Peltier element or a heater, similarly to the stage 17. The sidewall 45 is a wall that stands along the periphery of the calibration stage 46, and the insulating coolant 43 is supplied to the space (hereinafter, referred to as “coolant space”) surrounded by the sidewall 45.

In the case of using the calibration stage 46, first, the alignment is performed such that the temperature-measuring contact probes 33 of the temperature-measuring probe card 32 face the electrode pads 11a and 11b of each pattern 10 of the temperature-measuring wafer TW (see FIG. 6A).

Thereafter, the temperature-measuring contact probes 33 are brought into contact with the corresponding electrode pads 11a and 11b of each pattern 10, and the insulating coolant 43 is supplied to the coolant space to immerse the temperature-measuring wafer TW placed on the calibration stage 46 into the insulating coolant 43 (see FIG. 6B). Here, the temperature of the insulating coolant 43 is maintained at a desired temperature in the same manner as that in the case of using the calibration stage 39, and the temperature of the temperature-measuring wafer TW is adjusted to a desired temperature.

In this case as well, the temperature of the insulating coolant 43 is measured by the high-precision temperature sensor 44 of the substrate inspection device 38, and the electrical resistance value of each pattern 10 is also measured. Then, a correction value for converting the measured electrical resistance value into the measured temperature of the insulating coolant 43 is acquired for each pattern 10.

The temperature-measuring wafer TW is transferred to the calibration stage 46 in a state where the temperature-measuring wafer W is lifted by pins 47 to avoid interference with the sidewall 45 (see FIG. 6C).

Since it is assumed that the above-described substrate inspection device 38 is installed on the same inspection line as the substrate inspection device 12, the configuration thereof is basically the same as that of the substrate inspection device 12. However, if it is not assumed that the inspection device 48 is installed on the same inspection line as the substrate inspection device 12, the substrate inspection device for performing the correction value calibration operation may be configured more simply.

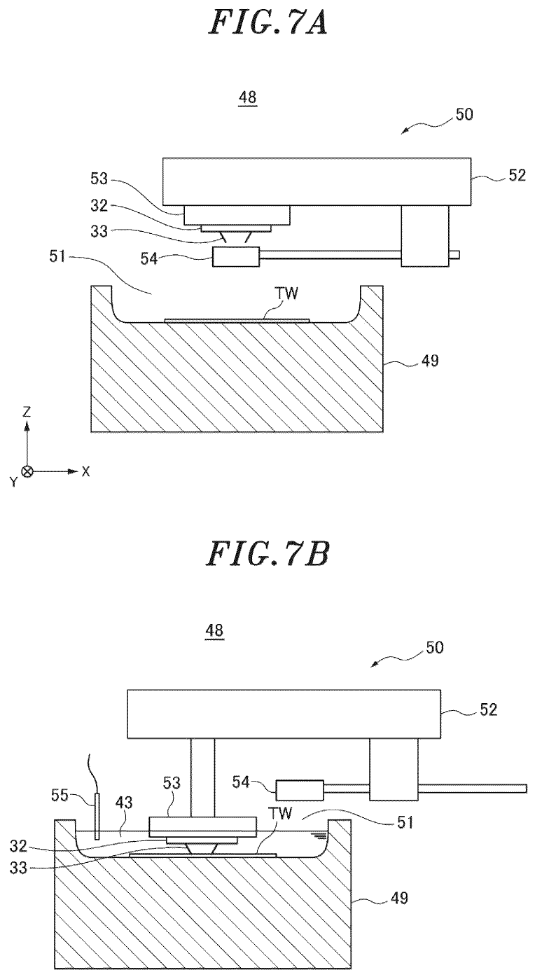

For example, as shown in FIG. 7A, the substrate inspection device 48 may include a stage 49 on which the temperature-measuring wafer TW is placed, and an inspection part 50 disposed above the stage 49. In this case, the stage 49 has a concave-shaped recess 51 on the upper surface thereof, and the temperature-measuring wafer TW is disposed at the bottom portion of the recess 51.

The stage 49 has a temperature adjustment mechanism (not shown) such as a Peltier element or a heater, similarly to the stage 17. The inspection part 50 has a base member 52 disposed to face the recess 51 of the stage 49, a card base 53 disposed on the bottom surface of the base member 52, and the temperature-measuring probe card 32 attached to the bottom surface of the card base 53. Further, the inspection part 50 has a camera 54 capable of moving between the temperature-measuring wafer TW disposed at the bottom portion of the recess 51 and the temperature-measuring probe card 32.

In the inspection part 50, the base member 52 is configured to be movable in two axial directions (the X and Y directions in the drawing), and the card base 53 is configured to be movable in the vertical direction (the Z direction in the drawing). Further, similarly to the substrate inspection device 38, the substrate inspection device 48 is also configured to be able to communicate with an external server 42 via the Internet 41.

In the case of performing the correction value calibration operation in the substrate inspection device 48, first, the camera 54 captures images of the temperature-measuring wafer TW from the top, thereby acquiring the positions of the electrode pads 11a and 11b of each pattern 10.

Then, the camera 54 moves out from the position between the temperature-measuring wafer TW disposed at the bottom portion of the recess 51 and the temperature-measuring probe card 32. Next, based on the positions of the electrode pads 11a and 11b of each pattern 10, the base member 52 moves in two axial directions so that the temperature-measuring contact probes 33 of the temperature-measuring probe card 32 face the electrode pads 11a and 11b of each pattern 10.

Then, the card base 53 moves downward to bring the temperature-measuring contact probes 33 of the temperature-measuring probe card 32 into contact with the corresponding electrode pads 11a and 11b of each pattern 10.

Then, the insulating coolant 43 is supplied to the recess 51 from a coolant supply port (not shown) disposed at the stage 49, and the temperature-measuring wafer TW disposed at the bottom portion of the recess 51 is immersed into the insulating coolant 43 (see FIG. 7B). The insulating coolant 43 supplied to the recess 51 circulates between the recess 51 and an external chiller to adjust the temperature to a desired temperature. By adjusting the temperature of the stage 49 using the temperature adjustment mechanism, the temperature of the insulating coolant 43 in the recess 51 is maintained at a desired temperature. Accordingly, the temperature of the temperature-measuring wafer TW is adjusted to a desired temperature.

The temperature of the insulating coolant 43 is measured by a high-precision temperature sensor 55 of the substrate inspection device 48, and the electrical resistance value of each pattern 10 is measured. Then, a correction value for converting the measured electrical resistance into the measured temperature of the insulating coolant 43 is acquired for each pattern 10. The acquired correction value is stored in the memory of the server 42 in association with the pattern 10 whose electrical resistance value used for acquiring the correction value is measured.

In accordance with the present embodiment, the temperature-measuring wafer TW is used for the stage calibration operation, and the temperature-measuring contact probes 33 of the temperature-measuring probe card 32 are brought into contact with the electrode pads 11a and 11b of each pattern 10 to measure the electrical resistance value for each pattern 10. In other words, since it is unnecessary to use a temperature-measuring wafer with multiple wiring for the stage calibration operation, an operator's manual handling of the temperature-measuring wafer is not required. For example, the temperature-measuring wafer TW can be transferred between the cassette C and the stage 17 by the wafer transfer mechanism of the loader part 13, so that the efficiency of the stage calibration operation is improved.

Further, in the present embodiment, the temperature-measuring wafer TW is used and, thus, it is unnecessary to check whether or not the wiring is disconnected. Accordingly, it is not required to increase the frequency of the calibration operation for checking whether or not the wiring is disconnected. Further, in the substrate inspection device 38, the temperature-measuring wafer TW can be transferred between the cassette C and the calibration stage 39 by the wafer transfer mechanism of the loader part 13, so that the efficiency of the correction value calibration operation is improved.

Further, in the present embodiment, the temperature-measuring wafer TW is immersed into the insulating coolant 43 during the correction value calibration operation. Thus, the temperature-measuring wafer TW is not exposed to the atmosphere, and it is possible to suppress the release of heat from the temperature-measuring wafer TW to the atmosphere. As a result, the temperature of the temperature-measuring wafer TW can be easily adjusted during the correction value calibration operation. Accordingly, the efficiency of the correction value calibration operation can be further improved.

In other words, in the present embodiment, the efficiency of both the stage calibration operation and the correction value calibration operation is improved, so that the efficiency of temperature measurement by the temperature-measuring wafer TW can be improved.

Further, in the above-described substrate inspection device 12, it is assumed that the probe card 20 for performing the stage calibration operation is replaced with the temperature-measuring probe card 32 by an operator manually. However, if the temperature-measuring probe card 32 has the same shape as that of the probe card 20, the temperature-measuring probe card 32 can be transferred and attached to the head plate 23 by a probe card transfer mechanism (not shown), e.g., a semi-automatic probe card changer (SACC), of the substrate inspection device 12. Accordingly, the efficiency of the stage calibration operation in the substrate inspection device 12 can be further improved.

While the embodiments of the present disclosure have been described above, the present disclosure is not limited to the above-described embodiments, and various changes and modifications may be made.

For example, in the above-described embodiment, in order to adjust the temperature of the temperature-measuring wafer TW to a desired temperature in the correction value calibration operation, the temperature-measuring wafer TW is immersed into the insulating coolant 43 whose temperature has been adjusted to a desired temperature. However, the method for adjusting the temperature of the temperature-measuring wafer TW in the correction value calibration operation is not limited thereto, and the temperature of the temperature-measuring wafer TW may be adjusted to a desired temperature without immersing the temperature-measuring wafer TW into the insulating coolant 43.

For example, the substrate inspection device 12 may be used, and the temperature-measuring probe card 32 may be attached to the head plate 23. The temperature-measuring wafer TW may be placed on the stage 17, and the temperature of the temperature-measuring wafer TW may be adjusted to a desired temperature by the temperature adjustment mechanism of the stage 17. In this case, as shown in FIG. 8, the temperature of the stage 17 is measured by the high-precision temperature sensor 44, and the correction value for converting the measured electrical resistance value of the pattern 10 to the measured temperature of the stage 17 is acquired. However, in this case, as described above, heat is released from the temperature-measuring wafer TW into the atmosphere, which is disadvantageous in that time is required to adjust the temperature of the temperature-measuring wafer TW. However, the correction value calibration operation can be performed simply by adding the high-precision temperature sensor 44 to a general substrate inspection device 12 for inspecting semiconductor devices on the product wafers W. Therefore, there is an advantage that it is unnecessary to use the substrate inspection device 38 or the substrate inspection device 48 having a special configuration specialized for the correction value calibration operation.

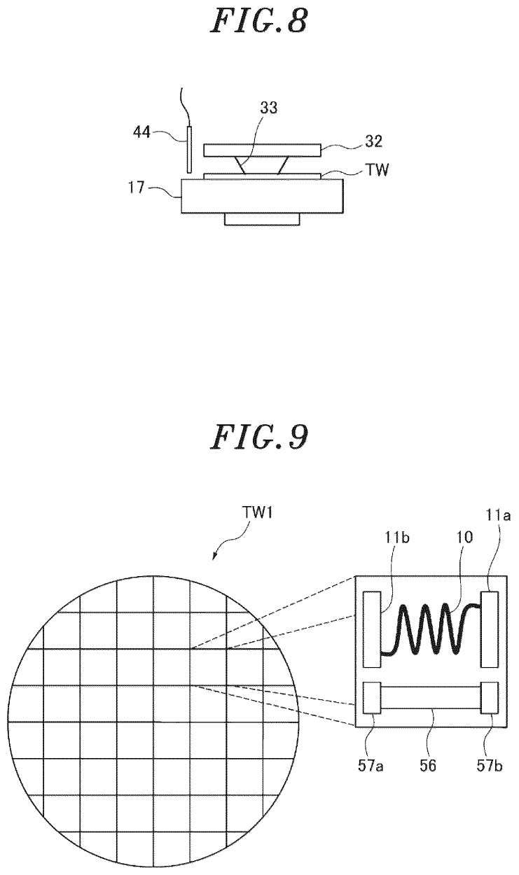

Further, since recent semiconductor devices, such as a graphics processing unit (GPU) or a central processing unit (CPU), are particularly highly-integrated and generate a large amount of heat, it is necessary to consider the influence of heat generation from the semiconductor devices in the inspection of the semiconductor devices. Further, in the stage calibration operation, it is also necessary to consider the influence of heat generation from the semiconductor devices on the temperature adjustment performance of the stage 17. Therefore, in a substrate inspection device for inspecting a product wafer W on which a GPU or a CPU is formed, a temperature-measuring wafer TW1 shown in FIG. 9 is used, instead of the temperature-measuring wafer TW, to perform the stage calibration operation.

As shown in FIG. 9, the temperature-measuring wafer TW1 has basically the same configuration as that of the temperature-measuring wafer TW, but is different in that heaters 56 (heating elements) are arranged to correspond to the multiple patterns 10. In other words, the pattern 10 and the heater 56 form a one-to-one pair, and the heaters 56 are arranged adjacent to the corresponding patterns 10. The pair of the pattern 10 and the heater 56 imitates a GPU or a CPU. The heater 56 is made of, e.g., a metal such as tungsten, a nickel-chromium alloy, silicon carbide (SiC), or carbon. Further, the heater 56 may be provided on the surface of the temperature-measuring wafer TW1, or may be embedded in the temperature-measuring wafer TW1.

Further, in the temperature-measuring wafer TW1, electrode pads 57a and 57b (other electrodes) are arranged on both ends of each heater 56. The electrode pads 57a and 57b are provided on the surface of the temperature-measuring wafer TW1. In the case of performing the stage calibration operation, the temperature-measuring contact probes 33 of the temperature-measuring probe card 32 are brought into contact not only with the electrode pads 11a and 11b of a certain pattern 10, but also with the electrode pads 57a and 57b of the heater 56 corresponding to the pattern 10. Further, by supplying electricity to the heater 56, the heater 56 generates heat and the heat generation of the semiconductor devices is reproduced.

Accordingly, in the stage calibration operation, the influence of the heat generation of the semiconductor devices on the temperature adjustment performance of the stage 17 may be considered. Even if multiple GPUs and CPUs are formed on the product wafer W, the multiple GPUs and CPUs are not inspected at the same time, and they are usually inspected one by one. Therefore, in the stage calibration operation using the temperature-measuring wafer TW1, the electrical resistance value of one pattern 10 is measured, and only the corresponding heater 56 generates heat. However, when the multiple GPUs or CPUs are inspected at the same time, the electrical resistance values of the multiple patterns 10 are measured, and the corresponding heaters 56 generate heat, even in the stage calibration operation using the temperature-measuring wafer TW1.

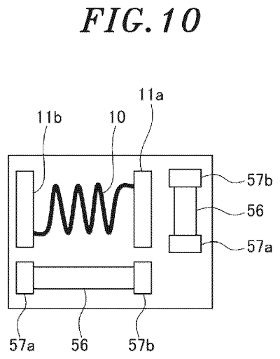

Further, the number of heater 56 arranged to correspond to each pattern 10 is not limited to one. For example, in order to imitate a GPU or a CPU that generates a larger amount of heat, multiple heaters 56, e.g., two heaters 56, may be arranged on one pattern 10 (see FIG. 10).

Further, in the correction value calibration operation described above, the correction value for directly converting the measured electrical resistance value of the pattern 10 into an actual temperature was acquired. However, the correction value for converting the temperature converted from the measured electrical resistance value of the pattern 10 based on the temperature resistance characteristics of platinum into an actual temperature may be acquired.

Further, in the correction value calibration operation described above, the temperature-measuring wafer TW was immersed into the insulating coolant 43 after the temperature-measuring contact probes 33 of the temperature-measuring probe card 32 were brought into contact with the corresponding electrode pads 11a and 11b of each pattern 10. However, the temperature-measuring contact probes 33 may be brought into contact with the corresponding electrode pads 11a and 11b after the temperature-measuring wafer TW is immersed into the insulating coolant 43.

Further, in the present embodiment, the case in which the technique of the present disclosure is applied to a single-wafer type substrate inspection device for inspecting product wafers W one by one has been described. However, the technique of the present disclosure may also be applied to a substrate inspection device of a multi-level multi-cell structure in which multiple inspection chambers (cells) are provided and multiple product wafers W can be inspected simultaneously by inspecting the product wafers W in the respective inspection chambers.

This application claims priority to Japanese Patent Application No. 2022-149201 filed on Sep. 20, 2022, the entire contents of which are incorporated herein by reference.

1. A method for calibrating a temperature-measuring substrate having a plurality of temperature-measuring resistors and electrodes arranged to correspond to the plurality of temperature-measuring resistors, the method comprising:
bringing a needle-shaped body into contact with an electrode corresponding to at least one temperature-measuring resistor;
immersing the temperature-measuring substrate into an insulating coolant;
measuring an electrical resistance value of the temperature-measuring resistor through the electrode using the needle-shaped body;
measuring a temperature of the insulating coolant; and
acquiring a correction value for converting the measured electrical resistance value to the measured temperature of the insulating coolant.

2. The method for calibrating a temperature-measuring substrate of claim 1, wherein the temperature of the temperature-measuring substrate immersed in the insulating coolant is adjusted to a desired temperature by adjusting the temperature of the insulating coolant.

3. The method for calibrating a temperature-measuring substrate of claim 1, wherein the temperature-measuring substrate is immersed into the insulating coolant after the needle-shaped body is brought into contact with the electrode.

4. The calibration method for a temperature-measuring substrate of claim 1, wherein the acquired correction value is stored in a storage device in association with the temperature-measuring resistor whose electrical resistance value was measured.

5. The calibration method for a temperature-measuring substrate of claim 1, wherein the electrical resistance value of the temperature-measuring resistor is measured after the temperature of the insulating coolant has stabilized.

6. The calibration method for a temperature-measuring substrate of claim 1, wherein the insulating coolant circulates between a coolant space and an external temperature adjustment device.

7. The calibration method for a temperature-measuring substrate of claim 1, wherein the insulating coolant is stirred or circulated.

8. The calibration method for a temperature-measuring substrate of claim 1, wherein the temperature-measuring resistor is made of a metal or metal oxide whose electrical resistance value changes depending on temperatures.

9. A method for calibrating a temperature-measuring substrate having a plurality of temperature-measuring resistors and electrodes arranged to correspond to the plurality of temperature-measuring resistors, the method comprising:
placing the temperature-measuring substrate on a placing member of which temperature is adjustable;
bringing a needle-shaped body into contact with an electrode corresponding to at least one temperature-measuring resistor;
measuring the electrical resistance value of the temperature-measuring resistor through the electrode using the needle-shaped body;
measuring the temperature of the placing member; and
acquiring a correction value for converting the measured electrical resistance value into the measured temperature of the placing member.

10. A substrate temperature-measuring system comprising:
a calibration device, a storage device, and an inspection device for inspecting semiconductor devices formed on a product substrate, wherein:
the calibration device acquires a correction value for converting an electrical resistance value of a temperature-measuring resistor of a temperature-measuring substrate, which has a plurality of temperature-measuring resistors and electrodes corresponding to the temperature-measuring resistors, into an actual temperature of each of the temperature-measuring resistors,
the calibration device, the storage device, and the inspection device are connected to communicate with each other via an information communication network,
the calibration device stores the acquired correction value, in association with the temperature-measuring resistor whose electrical resistance value was measured, in the storage device via the information communication network, and
the inspection device has a placing member that places the product substrate thereon and adjusts a temperature of the product substrate; and in the case of checking a temperature adjustment performance of the placing member using the temperature-measuring substrate, receives the correction value from the storage device via the information communication network and measures a temperature of each temperature-measuring resistor based on an electrical resistance value of each temperature-measuring resistor using the received correction value.

11. A temperature-measuring substrate having a plurality of temperature-measuring resistors and electrodes arranged to correspond to the plurality of temperature-measuring resistors,
wherein a heating element is disposed to correspond to each of the plurality of temperature-measuring resistors.

12. The temperature-measuring substrate of claim 11, wherein a plurality of the heating elements are arranged to correspond to one temperature-measuring resistor.

13. The temperature-measuring substrate of claim 11, wherein:
another electrode is disposed to correspond to each of the heating elements, and
electricity is supplied to each of the temperature-measuring resistors and each of the heating elements by bringing a needle-shaped body into contact with the electrode and said another electrode.

14. The temperature-measuring substrate of claim 11, wherein the temperature-measuring resistors and the heating elements arranged to correspond to the temperature-measuring resistors imitate a GPU or a CPU formed on a semiconductor wafer.
